(19) United States
(12) Patent Application Publication
(10) Pub. No.: US 2008/0036003 A1
(43) Pub. Date: Feb. 14, 2008

(54) Backlighted membrane switch

(75) Inventor: Yu Kai Lin, Taipei Hsien (TW)

Correspondence Address: CHARLES E. BAXLEY, ESQ., 90 JOHN STREET, THIRD FLOOR, NEW YORK, NY, 10038, US

(73) Assignee: Goda Technology Co., Ltd.

(21) Appl. No.: 11/501,934

(22) Filed: Aug. 9, 2006

(51) Int. Cl. H01L 23/62

(52) U.S. Cl. 257/355

(57) ABSTRACT

A backlighted membrane switch includes a circuit board having a number of switch contacts, a plate spaced away from the circuit board and having a number of conductor contacts aligned with the switch contacts of the printed circuit for being selectively depressed to engage with the switch contacts of the printed circuit by key pads. A spacing device may space the conductor contacts of the plate from the switch contacts of the printed circuit of the circuit board. An electroluminescent device is integrated onto the plate for being selectively energized to generate a backlight and for suitably reducing the weight and the thickness of the membrane switch, and the manufacturing processes and the cost of the membrane switch.

### BACKGROUND OF THE INVENTION

1. Field of the Invention

The present invention relates to a backlighted membrane switch, and more particularly to a backlighted membrane switch including a simplified structure for suitably reducing the weight and/or the thickness of the membrane switch, and for suitably reducing the manufacturing processes and the cost of the membrane switch.

2. Description of the Prior Art

Typical keyboards have been widely used for a long time and have no light devices disposed therein such that the key pads of the typical keyboards may not be easily seen by the users, particularly in the dark environment.

For allowing the key pads of the keyboards to be easily seen by the users, a number of light devices, such as light emitting diodes have been provided and engaged into the keyboards, particularly engaged into the key pads for suitably lighting or illuminating the key pads of the keyboards.

For example, U.S. Pat. No. 5,612,692 to Dugas et al. discloses one of the typical backlighted keyboards comprising a translucent membrane disposed between the keys and a printed circuit board, and a gasket disposed around the perimeter of the translucent membrane and sealingly engaged by the housing for the keyboard, in order to form a liquid tight seal between the keys and the printed circuit board.

However, the engagement of the light devices into the keyboards may greatly increase the weight and the thickness of the keyboard, and may also increase the manufacturing processes and the cost of the keyboard.

U.S. Pat. No. 7,057,125 to Tsai discloses another typical backlighted keyboard comprising a light guide board having multiple fastening members provided on top, multiple light refracting areas formed at a bottom surface, and multiple openings for receiving multiple illuminants respectively, and a membrane printed circuit board is disposed on the light guide board and has multiple nodes aligned with the fastening members, and a rubber button sheet has fastening members buttons aligned with the nodes. An illuminating board is further required to be provided and includes four illuminants or light emitting diodes engaged into the openings of the light guide board for illuminating purposes.

However, the provision and the engagement of the light devices into the keyboards may increase the weight and the thickness of the keyboard, and may also increase the manufacturing processes and the cost of the keyboard.

The present invention has arisen to mitigate and/or obviate the afore-described disadvantages of the conventional backlighted membrane switches.

### SUMMARY OF THE INVENTION

The primary objective of the present invention is to provide a backlighted membrane switch including a simplified structure for suitably reducing the weight and/or the thickness of the membrane switch, and for suitably reducing the manufacturing processes and the cost of the membrane switch.

In accordance with one aspect of the invention, there is provided a backlighted membrane switch comprising a number of key pads, a circuit board including a printed circuit disposed thereon and having a number of switch contacts provided thereon, a plate disposed above the circuit board and including a bottom portion facing toward the circuit board and having a number of conductor contacts attached thereto and aligned with the switch contacts of the printed circuit respectively and aligned with the key pads for being selectively depressed and forced to engage with the switch contacts of the printed circuit of the circuit board respectively, a spacing device for spacing the conductor contacts of the plate from the switch contacts of the printed circuit of the circuit board to allow the conductor contacts of the plate to be selectively forced to engage with the switch contacts of the printed circuit of the circuit board respectively, and an electroluminescent device integrated onto the plate for being selectively energized to generate a backlight, and the plate including a terminal electrically coupled to the electroluminescent device for allowing the electroluminescent device to be selectively operated and energized to generate the backlight.

The electroluminescent device includes a number of lighting areas aligned with the key pads and the conductor contacts of the plate. The lighting areas of the electroluminescent device are coupled together with conductor lines for allowing the lighting areas of the electroluminescent device to be energized and actuated to generate the backlight.

The spacing device includes a spacer disposed between the circuit board and the plate and having a number of openings formed therein and aligned with the switch contacts of the printed circuit of the circuit board and also aligned with the conductor contacts of the plate for partially receiving the switch contacts of the printed circuit of the circuit board and the conductor contacts of the plate.

The spacer may be simply disposed between the circuit board and the plate, or formed integral with the circuit board, or formed integral with the plate.

A covering may further be provided and engaged onto the outer peripheral portion of the circuit board and the spacer and the plate for suitably sealing the circuit board and the spacer and the plate of the membrane switch.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a partial exploded view of a backlighted membrane switch in accordance with the present invention as seen from the upper portion of one side thereof;

FIG. 2 is another partial exploded view of the backlighted membrane switch as seen from the front portion thereof;

FIG. 3 is a front plan schematic view of the backlighted membrane switch;

FIG. 4 is a partial cross sectional view of the backlighted membrane switch;

FIG. 5 is a partial exploded view of the backlighted membrane switch as seen from the front portion thereof, similar to FIG. 2, illustrating the other arrangement of the backlighted membrane switch; and

FIG. 6 is a further partial exploded view of the backlighted membrane switch as seen from the front portion thereof, similar to FIGS. 2 and 5, illustrating the further arrangement of the backlighted membrane switch.

### DETAILED DESCRIPTION OF THE PREFERRED EMBODIMENT

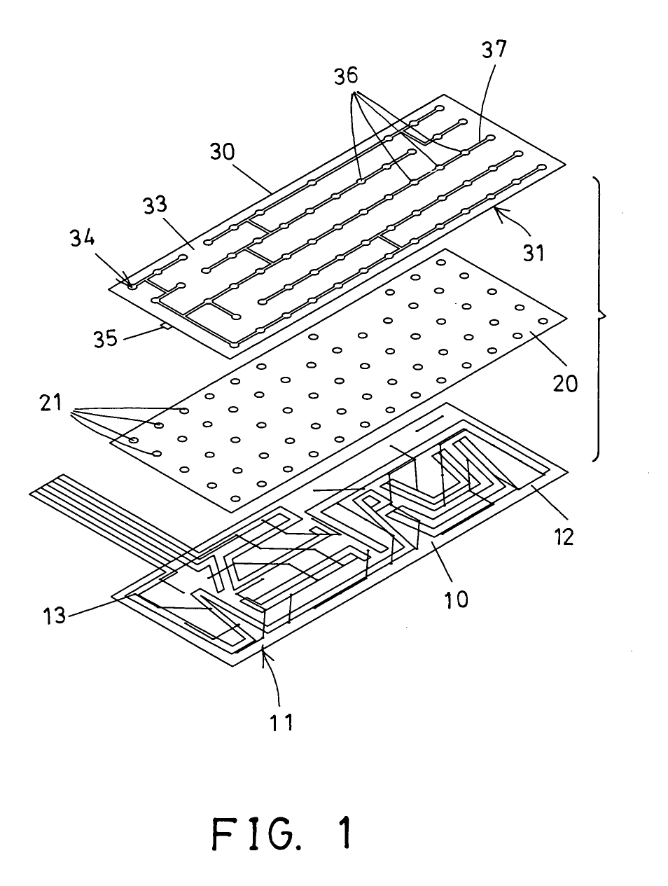

Referring to the drawings, and initially to FIGS. 1-3, a backlighted membrane switch 1 in accordance with the present invention comprises a base circuit board 10 to be disposed in an inner and bottom portion of a typical outer housing (not shown), the circuit board 10 includes one of the two sides, such as the upper side 11 having a printed circuit 12 applied or disposed or printed thereon and having a number of switch contacts 13 formed or provided thereon.

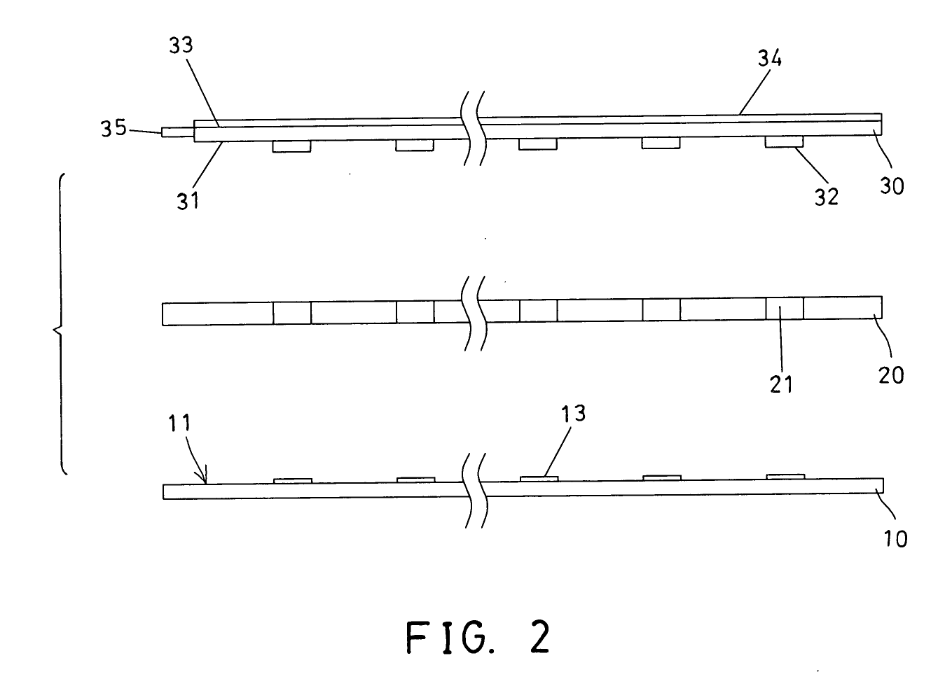

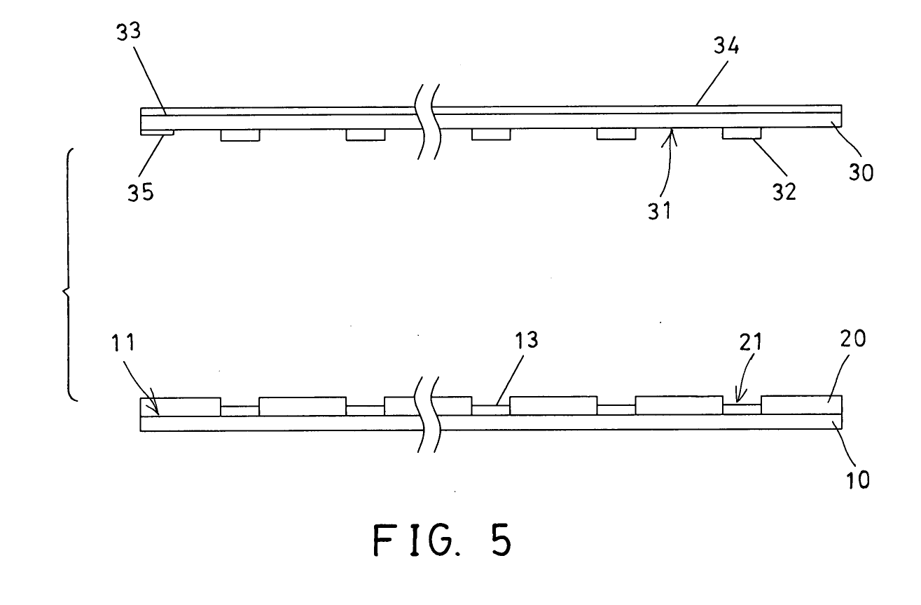

A soft or resilient spacer 20 is to be disposed or engaged onto the circuit board 10 and includes a number of openings 21 formed therein or provided therein and aligned with the switch contacts 13 of the printed circuit 12 of the circuit board 10 for allowing the switch contacts 13 to be partially engaged into the openings 21 of the soft or resilient spacer 20 (FIGS. 2-4). The soft or resilient spacer 20 may also be attached to or formed integral with the circuit board 10 as shown in FIG. 5.

The backlighted membrane switch 1 further includes a soft or resilient film or membrane or plate 30 to be disposed above the circuit board 10 or engaged onto the spacer 20 or arranged to have the spacer 20 disposed between the circuit board 10 and the plate 30, and includes a bottom portion 31 facing toward the circuit board 10 and having a number of conductor contacts 32 attached thereto or extended outwardly therefrom and aligned with the switch contacts 13 of the printed circuit 12 and also aligned with the openings 21 of the spacer 20 for allowing the conductor contacts 32 also to be partially engaged into the openings 21 of the soft or resilient spacer 20 (FIGS. 2-4).

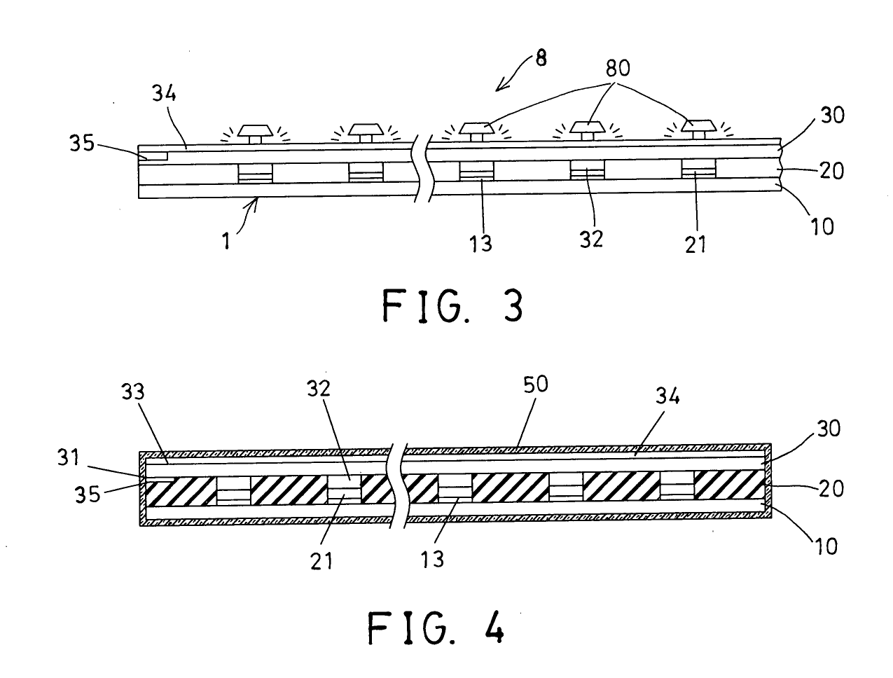

The conductor contacts 32 of the plate 30 are also aligned with the keys or key pads 80 of the backlighted membrane switch 1 (FIG. 3) for being selectively depressed or stricken or forced to engage with the switch contacts 13 of the printed circuit 12 of the circuit board 10. The soft or resilient spacer 20 may thus be used and acted as a spacing means or device for suitably or resiliently spacing the conductor contacts 32 of the plate 30 from the switch contacts 13 of the printed circuit 12 of the circuit board 10 and for allowing the conductor contacts 32 of the plate 30 to be selectively forced to engage with the switch contacts 13 of the printed circuit 12 of the circuit board 10.

The plate 30 further includes an upper portion 33 having an electroluminescent member or device 34 attached thereto or applied thereon or integrated therein and made of such as illuminating or electroluminescent materials, and further includes a terminal 35 attached thereto or provided thereon and electrically coupled to the electroluminescent member or device 34 for allowing the electroluminescent member or device 34 to be selectively operated or energized or actuated to generate a backlight when an electric energy is supplied to the terminal 35 and then to the electroluminescent member or device 34. The electroluminescent member or device 34 may also be directly integrated into the plate 30.

For example, as best shown in FIG. 1, the electroluminescent device 34 may preferably include a number of dots or lighting areas 36 aligned with the conductor contacts 32 of the plate 30 and also aligned with the switch contacts 13 of the printed circuit 12 of the circuit board 10 and also aligned with the openings 21 of the spacer 20, and coupled together with conductor lines 37 for allowing the lighting areas 36 of the electroluminescent device 34 to be suitably energized or actuated to generate the backlight.

In operation, as shown in FIG. 3, the backlighted membrane switch 1 may be attached or engaged into an electric facility 8, such as a keyboard 8 which includes a number of keys or key pads 80 for aligning with the dots or lighting areas 36 of the electroluminescent device 34 and for allowing the lighting areas 36 of the electroluminescent device 34 to be suitably depressed or actuated with the keys or key pads 80 of the keyboard 8 or the electric facility 8.

It is to be noted that the electroluminescent device 34 includes a thin or greatly reduced thickness and weight as compared with the light devices of the typical backlighted membrane switches, and the electroluminescent device 34 may also be easily and quickly applied or disposed or printed onto or integrated into the plate 30 such that the manufacturing procedures may be greatly simplified and the manufacturing for the backlighted membrane switch 1 may also be suitably reduced.

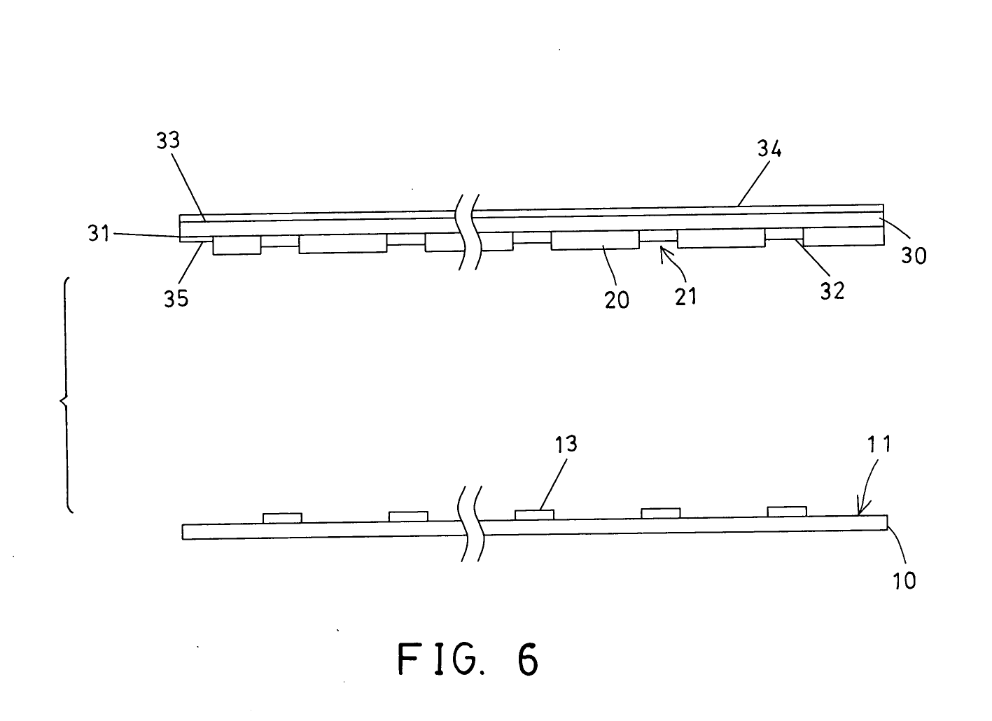

As shown in FIG. 4, a sheath or covering 50 may further be provided and engaged onto the outer peripheral portion of the circuit board 10, the spacer 20, and the plate 30 for forming or making a liquid or fluid tight seal to the backlighted membrane switch 1 or for suitably sealing the circuit board 10 and the spacer 20 and the plate 30, and for preventing the circuit board 10 and the spacer 20 and the plate 30 from being wetted or damaged by humidity. As shown in FIG. 6, the soft or resilient spacer 20 may also be attached to or formed integral with the plate 30.

Accordingly, the backlighted membrane switch in accordance with the present invention includes a simplified structure for suitably reducing the weight and/or the thickness of the membrane switch, and for suitably reducing the manufacturing processes and the cost of the membrane switch.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A backlighted membrane switch comprising:
a circuit board including a printed circuit disposed thereon and having a plurality of switch contacts provided thereon,
a plate disposed above said circuit board and including a bottom portion facing toward said circuit board and having a plurality of conductor contacts attached thereto and aligned with said switch contacts of said printed circuit respectively for being selectively depressed and forced to engage with said switch contacts of said printed circuit of said circuit board respectively,
means for spacing said conductor contacts of said plate from said switch contacts of said printed circuit of said circuit board to allow said conductor contacts of said plate to be selectively forced to engage with said switch contacts of said printed circuit of said circuit board respectively, and
an electroluminescent device integrated onto said plate for being selectively energized to generate a backlight, and said plate including a terminal electrically coupled to said electroluminescent device for allowing said electroluminescent device to be selectively operated and energized to generate the backlight.

2. The backlighted membrane switch as claimed in claim 1, wherein said electroluminescent device includes a plurality of lighting areas aligned with said conductor contacts of said plate.

3. The backlighted membrane switch as claimed in claim 2, wherein said lighting areas of said electroluminescent device are coupled together with conductor lines for allowing said lighting areas of said electroluminescent device to be energized and actuated to generate the backlight.

4. The backlighted membrane switch as claimed in claim 1, wherein said spacing means includes a spacer disposed between said circuit board and said plate and having a plurality of openings formed therein and aligned with said switch contacts of said printed circuit of said circuit board and also aligned with said conductor contacts of said plate for partially receiving said switch contacts of said printed circuit of said circuit board and said conductor contacts of said plate.

5. The backlighted membrane switch as claimed in claim 4, wherein said spacer is formed integral with said circuit board.

6. The backlighted membrane switch as claimed in claim 4, wherein said spacer is formed integral with said plate.

7. The backlighted membrane switch as claimed in claim 1, wherein a covering is engaged onto said circuit board and said spacer and said plate for sealing said circuit board and said spacer and said plate.

8. The backlighted membrane switch as claimed in claim 1 further comprising a plurality of key pads aligned with said conductor contacts of said plate for selectively forcing said conductor contacts of said plate to engage with said switch contacts of said printed circuit of said circuit board respectively.
